(19) United States
(12) Patent Application Publication
(10) Pub. No.: US 2024/0297054 A1
(43) Pub. Date: Sep. 5, 2024

(54) SUBSTRATE PROCESSING APPARATUS, SUBSTRATE PROCESSING SYSTEM, ELECTRICAL POWER SUPPLY SYSTEM, AND ELECTRICAL POWER SUPPLY METHOD

(71) Applicant: Tokyo Electron Limited, Tokyo (JP)

(72) Inventors: Naoki MATSUMOTO, Miyagi (JP); Shinya TAMONOKI, Miyagi (JP); Koichi NAGAMI, Miyagi (JP); Shinya ISHIKAWA, Miyagi (JP); Naoki FUJIWARA, Miyagi (JP); Naoki MIHARA, Miyagi (JP)

(73) Assignee: Tokyo Electron Limited, Tokyo (JP)

(21) Appl. No.: 18/660,822

(22) Filed: May 10, 2024

Related U.S. Application Data
(63) Continuation of application No. PCT/JP2022/041701, filed on Nov. 9, 2022.
(60) Provisional application No. 63/278,721, filed on Nov. 12, 2021.

(30) Foreign Application Priority Data
Jun. 23, 2022 (JP) 2022-101022

(51) Int. Cl. H01L 21/67; H01L 21/677; H01L 21/687

(52) U.S. Cl. CPC H01L 21/67115; H01L 21/67706; H01L 21/68764

(57) ABSTRACT

There is a substrate processing apparatus for processing a substrate, comprising: a power receiver including a power reception coil to which power is transmitted in a non-contact manner from a power transmission coil located outside the substrate processing apparatus, wherein the substrate processing apparatus is configured to supply power to at least one unit or member that uses power from the power receiver.

### CROSS-REFERENCE TO RELATED APPLICATIONS

This application is a bypass continuation application of International Application No. PCT/JP2022/041701 having an international filing date of Nov. 9, 2022 and designating the United States, the International Application being based upon and claiming the benefit of priority from U.S. Patent Application No. 63/278,721 filed on Nov. 12, 2021 and Japanese Patent Application No. 2022-101022 filed on Jun. 23, 2022, the entire contents of each are incorporated herein by reference.

### TECHNICAL FIELD

The present disclosure relates to a substrate processing apparatus, a substrate processing system, an electrical power supply system, and an electrical power supply method.

### BACKGROUND

JP Patent Publication No. 2015-173027 discloses a plasma processing apparatus as a substrate processing apparatus. The plasma processing apparatus uses a filter to attenuate or block radio frequency noise that enters a power supply line from electrical members other than a radio frequency electrode in a processing container.

### SUMMARY

The present disclosure provides a substrate processing apparatus, a substrate processing system, an electrical power supply system, and an electrical power supply method, which can simplify electrical connection wiring.

One aspect of the present disclosure is to provide a substrate processing apparatus for processing a substrate, the apparatus including a power receiver including a power reception coil to which electrical power is transmitted in a non-contact manner from a power transmission coil located outside the substrate processing apparatus. The apparatus is configured to supply electrical power to at least one of a unit or a member that uses power from the power receiver.

### BRIEF DESCRIPTION OF THE DRAWINGS

FIG. 1 is a diagram for explaining a configuration example of a plasma processing system according to an embodiment.

FIG. 2 is a diagram for explaining a configuration example of a capacitively coupled plasma processing apparatus.

FIG. 3 is a plan view schematically showing the configuration of a substrate processing system.

FIG. 4 is a side view schematically showing the configuration of the substrate processing system.

FIG. 5 is a conceptual diagram showing the schematic configuration of an electrical power supply system.

FIGS. 6A and 6B are schematic explanatory diagrams regarding the arrangement relationship between a power transmission coil and a power reception coil.

FIGS. 7A to 7H are schematic explanatory diagrams showing the opposing relationships between coils.

FIG. 8 is a conceptual diagram showing a schematic configuration when a frequency conversion circuit is included in the electrical power supply system.

FIG. 9 is a conceptual diagram showing a schematic configuration of an electrical power supply system according to another embodiment.

FIG. 10 is a conceptual diagram showing a schematic configuration when a frequency conversion circuit is included in an electrical power supply system according to another embodiment.

FIG. 11 is a diagram for explaining a configuration example of a capacitively coupled plasma processing apparatus in a reference example.

FIG. 12 is a conceptual diagram showing a schematic configuration of an electrical power supply system of a plasma processing apparatus according to an embodiment in a reference example.

### DETAILED DESCRIPTION

In a substrate processing apparatus or a substrate processing system, various members are electrically connected to an external power source. Therefore, a plurality of connection wirings are installed around the substrate processing apparatus or the substrate processing system. If the number of connection wirings increases, wiring confusion may occur when starting up or updating the apparatus, and wiring installation or removal work may be complicated when installing or removing the apparatus. Further, in a clean room layout in which the substrate processing apparatus is arranged, it may be difficult to change the layout due to non-uniform lengths of electrical power cables as the connection wiring.

Further, a plasma processing apparatus serving as the substrate processing apparatus includes an RF power source as a source of RF power for generating plasma in a processing container. Some of the RF applied by the RF power source may propagate as noise through the connection wiring. The propagated RF noise may harm the operation or performance of the external power source. The external power source is, for example, a factory power source as factory power. JP Patent Publication No. 2015-173027 discloses an RF filter that attenuates or blocks the RF noise so as to prevent or suppress the propagation of the RF noise as the external power source.

However, as described above, an increase in the number of connection wirings may cause a problem in the substrate processing apparatus or the substrate processing system, and there is a need to prevent the wiring confusion or to simplify wiring installation or removal work when installing or removing the apparatus. Further, in technology described in JP Patent Publication No. 2015-173027, it is required to provide a filter that attenuates or blocks radio-frequency noise in addition to the connection wiring, so there is concern about an increase in equipment cost. Further, there are concerns about an increase in man-hours and costs when starting up, installing, removing, and relocating the apparatus, and there is a need to reduce them.

The technology according to the present disclosure has been made in view of the above circumstances, and provides a configuration that may transfer electrical power while eliminating the need for connection wiring between the substrate processing apparatus or the substrate processing system and utility equipment, or connection wiring in the periphery thereof. Further, the present disclosure provides a configuration that may suppress the influence of the RF noise on the external power source, which is a problem in the plasma processing apparatus or the plasma processing system.

Hereinafter, a plasma processing apparatus as the substrate processing apparatus, a plasma processing system as the substrate processing system, and an electrical power supply system according to an embodiment of the present disclosure will be described with reference to the drawings. In this specification and drawings, elements having substantially the same functional configuration are given the same reference numerals, thereby omitting redundant description.

### <Plasma Processing System>

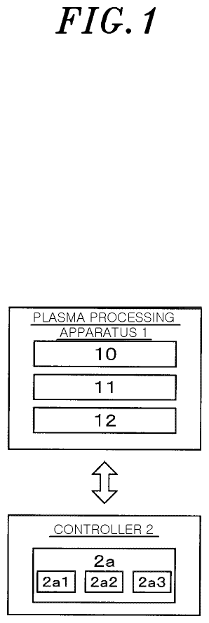

First, the plasma processing system according to an embodiment will be described. FIG. 1 is a diagram for explaining a configuration example of the plasma processing system according to an embodiment.

In an embodiment, the plasma processing system includes a plasma processing apparatus 1 and a controller 2. The plasma processing system is an example of the substrate processing system, and the plasma processing apparatus 1 is an example of the substrate processing apparatus. The plasma processing apparatus 1 includes a plasma processing chamber 10, a substrate support 11, and a plasma generator 12. The plasma processing chamber 10 has a plasma processing space. The plasma processing chamber 10 also includes at least one gas supply port for supplying at least one processing gas to the plasma processing space, and at least one gas discharge port for discharging gas from the plasma processing space. The gas supply port is connected to a gas supply part 20 that will be described later, and the gas discharge port is connected to an exhaust system 40 that will be described later. The substrate support 11 is disposed in the plasma processing space, and has a substrate support surface for supporting a substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-resonance (ECR) plasma, Helicon Wave Plasma (HWP), or Surface Wave Plasma (SWP). Further, various types of plasma generators, including an Alternating Current (hereinafter simply referred to as AC) plasma generator and a Direct Current (hereinafter simply referred to as DC) plasma generator, may be used. In an embodiment, an AC signal (AC power) used in the AC plasma generator has a frequency within the range of 100 kHz to 10 GHz. Therefore, the AC signal includes an RF (Radio Frequency) signal and a microwave signal. In an embodiment, the RF signal has a frequency within the range of 100 kHz to 150 MHz.

The controller 2 processes a computer-executable instruction that causes the plasma processing apparatus 1 to perform various processes described in the present disclosure. The controller 2 may control each element of the plasma processing apparatus 1 to execute various processes described herein. In an embodiment, part or all of the controller 2 may be included in the plasma processing apparatus 1. The controller 2 may include a processor 2a1, a memory 2a2, and a communication interface 2a3. The controller 2 is realized by, for example, a computer 2a. The processor 2a1 may be configured to perform various control operations by reading a program from the memory 2a2 and executing the read program. This program may be previously stored in the memory 2a2, and may be acquired via a medium when necessary. The acquired program is stored in the memory 2a2, and is read from the memory 2a2 and executed by the processor 2a1. The medium may be various storage media that may be read by the computer 2a, or may be a communication line connected to the communication interface 2a3. The processor 2a1 may be a Central Processing Unit (CPU). The memory 2a2 may include a Random Access Memory (RAM), a Read Only Memory (ROM), a Hard Disk Drive (HDD), a Solid State Drive (SSD), or a combination thereof. The communication interface 2a3 may communicate with the plasma processing apparatus 1 via the communication line such as a Local Area Network (LAN).

### <Plasma Processing Apparatus>

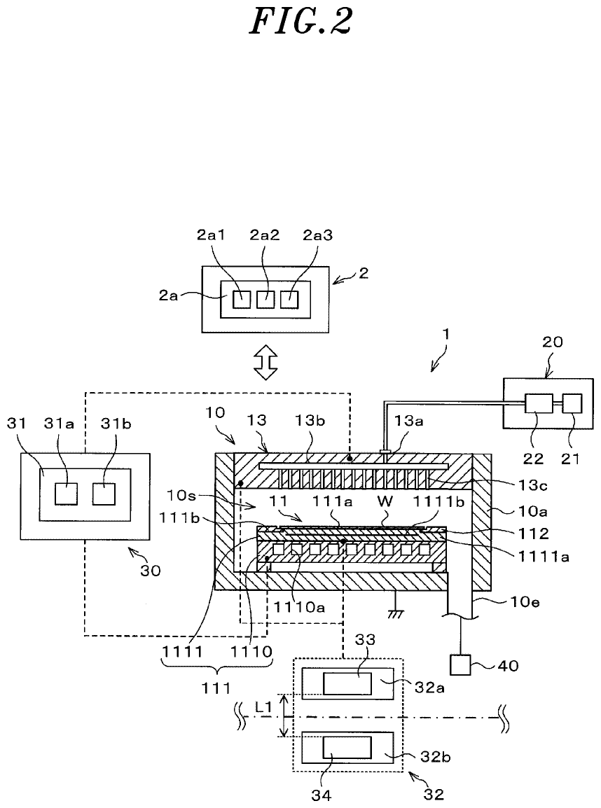

Hereinafter, the configuration example of the capacitively coupled plasma processing apparatus as an example of the plasma processing apparatus 1 will be described. FIG. 2 is a diagram for explaining the configuration example of the capacitively coupled plasma processing apparatus 1.

The capacitively coupled plasma processing apparatus 1 includes a plasma processing chamber 10, a gas supply part 20, a power source 30, and an exhaust system 40. Further, the plasma processing apparatus 1 includes a substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 forms at least part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central area 111a for supporting the substrate W, and an annular area 111b for supporting the ring assembly 112. The annular area 111b of the main body 111 surrounds the central area 111a of the main body 111 in a plan view. The substrate W is disposed on the central area 111a of the main body 111, and the ring assembly 112 is disposed on the annular area 111b of the main body 111 to surround the substrate W on the central area 111a of the main body 111. Therefore, the central area 111a is also called a substrate support surface for supporting the substrate W, and the annular area 111b is also called a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central area 111a. In an embodiment, the ceramic member 1111a also has an annular area 111b. Further, other members surrounding the central area 111a of the electrostatic chuck 1111, such as an annular electrostatic chuck or an annular insulating member, may be provided in the annular area 111b. In this case, the ring assembly 112 may be disposed on the annular electrostatic chuck or the annular insulating member, and may be disposed on both the central area 111a of the electrostatic chuck 1111 and the annular insulating member. Further, at least one RF/DC electrode coupled to an RF power source 31 and/or a wireless power feeder 32, which will be described later, may be disposed within the ceramic member 1111a. In this case, at least one RF/DC electrode functions as a lower electrode. When a bias RF signal and/or a DC signal, which will be described later, is supplied to at least one RF/DC electrode, the RF/DC electrode is also referred to as a bias electrode. Further, the conductive member of the base 1110 and at least one RF/DC electrode may function as a plurality of lower electrodes. Further, the electrostatic electrode 1111b may function as a lower electrode. Therefore, the substrate support 11 includes at least one lower electrode.

The ring assembly 112 includes one or more annular members. In an embodiment, one or more annular members include one or more edge rings and at least one cover ring. The edge ring is formed of a conductive or insulating material, and the cover ring is formed of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid such as brine or gas flows through the flow path 1110a. In an embodiment, the flow path 1110a is formed in the base 1110, and one or more heaters are disposed in the ceramic member 1111a of the electrostatic chuck 1111. Further, the substrate support 11 may include a heat transfer gas supply part configured to supply heat transfer gas to a gap between the back surface of the substrate W and the central area 111a.

The shower head 13 is configured to introduce at least one processing gas from the gas supply part 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and then is introduced from the plurality of gas introduction ports 13c into the plasma processing space 10s. Further, the shower head 13 includes at least one upper electrode. In addition to the shower head 13, the gas introducer may include one or more side gas injectors (SGI) installed in one or more openings formed in the side wall 10a.

The gas supply part 20 may include at least one gas source 21 and at least one flow controller 22. In an embodiment, the gas supply part 20 is configured to supply at least one processing gas from a corresponding gas source 21 through a corresponding flow controller 22 to the shower head 13. The flow controller 22 may include, for example, a mass flow controller or a pressure-controlled flow controller. Further, the gas supply part 20 may include at least one flow modulation device that modulates or pulses the flow rate of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. Thereby, plasma is formed from at least one processing gas supplied to the plasma processing space 10s. Therefore, the RF power source 31 may function as at least a part of the plasma generator 12. Further, by supplying a bias RF signal to at least one lower electrode, a bias potential may be generated on the substrate W, and ion components in the formed plasma may be drawn/attracted into the substrate W.

In an embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF electrical power) for plasma generation. In an embodiment, the source RF signal has a frequency within the range of 10 MHz to 150 MHz. In an embodiment, the first RF generator 31a may be configured to generate a plurality of source RF signals having different frequencies. One or more generated source RF signals are supplied to at least one lower electrode and/or at least one upper electrode.

The second RF generator 31b is coupled to at least one lower electrode via at least one impedance matching circuit, and is configured to generate a bias RF signal (bias RF electrical power). The frequency of the bias RF signal may be equal to or different from the frequency of the source RF signal. In an embodiment, the bias RF signal has a frequency that is lower than the frequency of the source RF signal. In an embodiment, the bias RF signal has a frequency within the range of 100 kHz to 60 MHz. In an embodiment, the second RF generator 31b may be configured to generate a plurality of bias RF signals having different frequencies. One or more generated bias RF signals are supplied to at least one lower electrode. Further, in various embodiments, at least one of the source RF signal and the bias RF signal may be pulsed.

The plasma processing apparatus 1 also includes a wireless power feeder 32 that supplies power to the plasma processing apparatus 1. The wireless power feeder 32 includes a power receiver 32a and a power transmitter 32b. In an embodiment, the power receiver 32a includes a power reception coil 33, and the power transmitter 32b includes a power transmission coil 34. In an embodiment, the power receiver 32a is provided in the plasma processing apparatus 1, and the power transmitter 32b is provided outside the plasma processing apparatus 1, so that the power receiver 32a and the power transmitter 32b are physically separated with each other. The power receiver 32a is electrically connected to a member inside the plasma processing chamber 10. In an embodiment, the power receiver 32a is electrically connected to at least one lower electrode and/or at least one upper electrode. In an embodiment, the power transmitter 32b is located outside the plasma processing apparatus 1, and is disposed, for example, on a bottom surface or under a bottom where the plasma processing apparatus 1 is installed. The power transmission coil 34 and the power reception coil 33 are physically separated, and the separation distance L1 may be a distance where the propagation of RF noise may be suppressed and electrical power may be supplied, for example, 1 mm or more and 200 mm or less, preferably 5 mm or more and 150 mm or less, and more preferably 10 mm or more and 100 mm or less. The separation distance L1 is a distance between the opposing surfaces of the power transmission coil 34 and the power reception coil 33. In the wireless power feeder 32, AC power is supplied from the AC power supply source to the power transmitter 32b, and the AC power is transmitted from the power transmission coil 34 to the power reception coil 33 in a non-contact manner. In an embodiment, the power transmitter 32b may convert the frequency using a frequency conversion circuit such as an AC/AC converter, and supply the AC power to the power receiver 32a. In an embodiment, a transmission method may be, for example, a magnetic field resonance method (also referred to as a magnetic resonance method), an electromagnetic induction method, or an electric field coupling method. A conversion circuit such as an AC/DC converter (not shown) converts the AC power received by the power reception coil 33 into DC power, and supplies the DC power to a member inside the plasma processing chamber 10. Further, in an embodiment, the generated AC power may be supplied as is.

In an embodiment, the power receiver 32a may include a DC generator (not shown) that generates a DC signal. The generated DC signal may be pulsed. In this case, a sequence of a voltage pulse is applied to at least one lower electrode and/or at least one upper electrode. The voltage pulse may have a pulse waveform that is rectangular, trapezoidal, triangular, or a combination thereof. The voltage pulse may have positive polarity or negative polarity. Further, the sequence of the voltage pulse may include one or more positive voltage pulses and one or more negative voltage pulses within one period. That is, the plasma processing apparatus 1, its constituent member, or its peripheral member includes a unit or member that is operated using DC power.

The exhaust system 40 may be connected to a gas discharge port 10e that is provided on the bottom of the plasma processing chamber 10, for instance. The exhaust system 40 may include a pressure regulating valve and a vacuum pump. The pressure in the plasma processing space 10s is regulated by the pressure regulating valve. The vacuum pump may include a turbo molecular pump, a dry pump, or a combination thereof.

### <Substrate Processing System>

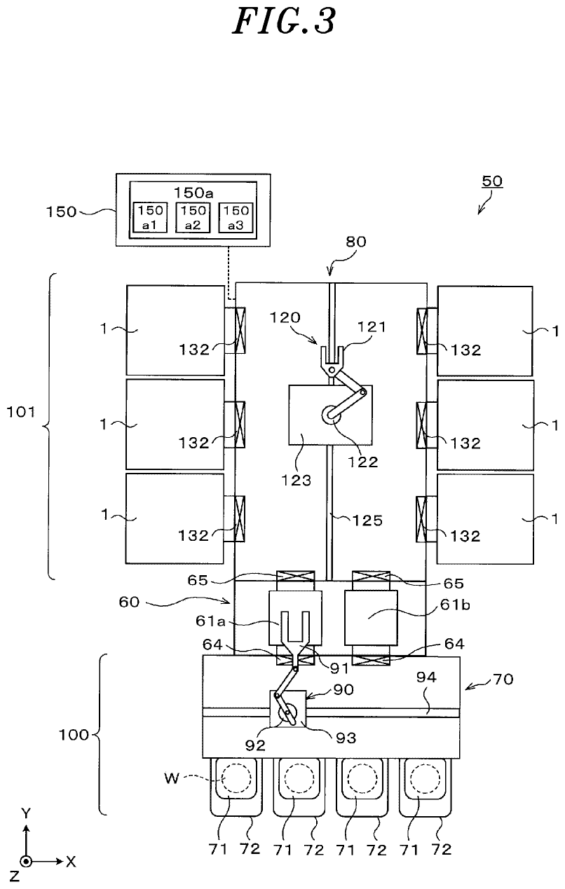

Next, a substrate processing system, which is an example of a specific configuration of the plasma processing system including the plasma processing apparatus 1 described above, will be described. FIG. 3 is a plan view schematically showing the configuration of the substrate processing system 50. Further, FIG. 4 is a side view schematically showing the configuration of the substrate processing system 50. In this embodiment, a case in which the substrate processing system 50 includes plasma processing apparatuses 1 at a plurality of locations (six locations) for plasma processing such as etching processing or film forming processing on the substrate W. However, the module configuration of the substrate processing system 50 according to the present disclosure may be selected depending on the purpose of substrate processing without being limited thereto.

As shown in FIG. 3, the substrate processing system 50 has a configuration in which an atmospheric section 100 and a pressure reduction section 101 are integrally connected with a load lock module 60 interposed therebetween.

The load lock module 60 has a plurality of load locks, for example, two load locks 61a and 61b in this embodiment along the width direction (X-axis direction) of a loader module 70, which will be described later. The load locks 61a and 61b (hereinafter sometimes simply referred to as a “load lock 61”) are provided to communicate an internal space of the loader module 70 in the atmospheric section 100 which will be described later and an internal space of a transfer module 80 in the pressure reduction section 101 which will be described later via a substrate transfer port. The substrate transfer port is configured to be opened or closed by each gate valve 64 or 65.

The load lock 61 is configured to temporarily hold the substrate W. Further, the load lock 61 is configured such that an interior thereof may be switched between an atmospheric atmosphere and a reduced pressure atmosphere (vacuum state). That is, the load lock module 60 is configured to appropriately transfer the substrate W between the atmospheric section 100 in the atmospheric atmosphere and the pressure reduction section 101 in the reduced pressure atmosphere.

The atmospheric section 100 includes the loader module 70 equipped with a substrate transfer device 90 that will be described later, and a load port 72 on which a hoop 71 capable of storing a plurality of substrates W is mounted. An orienter module (not shown) that adjusts the horizontal direction of the substrate W or a storage module (not shown) that stores a plurality of substrates W, etc. may be provided adjacent to the loader module 70.

The loader module 70 has a rectangular housing, and the inside of the housing is maintained in an atmospheric atmosphere. A plurality of load ports, for example, four load ports 72 are arranged side by side on a side of the loader module 70 that forms a long side on a negative side in the Y-axis direction. The load locks 61a and 61b of the load lock module 60 are arranged side by side on the other side of the loader module 70 that forms a long side on a positive side in the Y-axis direction.

The substrate transfer device 90 is provided in the loader module 70 to transfer the substrate W. The substrate transfer device 90 includes a transfer arm 91 that holds and moves the substrate W, a rotary table 92 that rotatably supports the transfer arm 91, and a rotary mounting table 93 on which the rotary table 92 is mounted. Further, a guide rail 94 extending in a longitudinal direction (X-axis direction) of the loader module 70 is provided in the loader module 70. The rotary mounting table 93 is provided on the guide rail 94, and the substrate transfer device 90 is configured to be movable along the guide rail 94.

The pressure reduction section 101 includes a transfer module 80 that transfers the substrate W therein, and a processing module (corresponding to the above-described plasma processing apparatus 1) that performs desired processing on the substrate W transferred from the transfer module 80. The interior of each of the transfer module 80 and the processing module is configured to be maintained in a reduced pressure atmosphere. In this embodiment, a plurality of processing modules, for example, six processing modules are connected to one transfer module 80. In addition, the number and arrangement of processing modules may be optionally set without being limited to this embodiment.

The transfer module 80 as a vacuum transfer module is connected to the load lock module 60. For example, the transfer module 80 transfers the substrate W carried into the load lock 61a of the load lock module 60 to one processing module to perform desired processing, and transfers the substrate to the atmospheric section 100 through the load lock 61b of the load lock module 60. In an embodiment, the transfer module 80 has a vacuum transfer space and an opening. The opening communicates with the vacuum transfer space.

A substrate transfer device 120 is provided in the transfer module 80 to transfer the substrate W. That is, the substrate transfer device 120 is disposed in the vacuum transfer space of the vacuum transfer module. The substrate transfer device 120 includes a transfer arm 121 that holds and moves the substrate W, a rotary table 122 that rotatably supports the transfer arm 121, and a rotary mounting table 123 on which the rotary table 122 is mounted. The rotary mounting table 123 is provided on a guide rail 125 extending in a longitudinal direction (Y-axis direction) of the transfer module 80, and the substrate transfer device 120 is configured to move along the guide rail 125.

The processing module (plasma processing apparatus 1) performs plasma processing, such as etching processing or film forming processing, on the substrate W. As the processing module, a module that performs processing depending on the purpose of substrate processing may be selected. Further, the processing module communicates with the transfer module 80 through a substrate transfer port formed on a side wall surface of the transfer module 80, and the substrate transfer port is configured to be opened or closed using a gate valve 132.

Further, as shown in FIG. 4, a wireless power feeder 140 that supplies power to the entire substrate processing system 50 is electrically connected to the substrate processing system 50 according to an embodiment. The wireless power feeder 140 includes a power receiver 140a provided on a side of the substrate processing system 50, and a power transmitter 140b provided outside the substrate processing system 50. In an embodiment, a power reception coil 143 is included in the power receiver 140a, and a power transmission coil 144 is included in the power transmitter 140b. In an embodiment, the power receiver 140a and the power transmitter 140b are physically separated. The separation distance L2 may be a distance where the propagation of RF noise may be suppressed and electrical power may be supplied, for example, 1 mm or more and 200 mm or less, preferably 5 mm or more and 150 mm or less, and more preferably 10 mm or more and 100 mm or less. In an embodiment, the power receiver 140a is provided on a bottom of the load lock module 60, for example, a bottom surface. In an embodiment, the power transmitter 140b is located below the power receiver 140a to face it and is provided on the bottom surface or under the bottom where the substrate processing system 50 is installed. Further, in an embodiment, the power receiver 140a may be provided on the side of the substrate processing system 50, for example, on the side surface thereof. In that case, the power transmitter 140b may be provided at a location corresponding to the power receiver 140a on the side surface of the substrate processing system 50. Although a case where the power receiver 140a is provided on the bottom of the load lock module 60 is illustrated, the location of the power receiver 140a is not limited thereto. For instance, the power receiver may be provided on the bottom of the transfer module 80, the bottom of the loader module 70, or the bottom of the processing module. In that case, the power transmitter 140b is located below the power receiver 140a to face it, and is provided on the bottom surface or under the bottom where the substrate processing system 50 is installed. Further, the power receiver 140a may be provided on each processing module, transfer module 80 or loader module 70. In that case, the power transmitter 140b is located below each power receiver 140a to face it, and is provided on the bottom surface or under the bottom where the substrate processing system 50 is installed. The location of the power receiver 140a in each module is not limited to the bottom, and the power transmitter 140b is provided at a location facing each power receiver 140a.

Further, as another example, electrical power supplied to one power receiver provided in the substrate processing system 50 may be distributed to each processing module, transfer module 80 or loader module 70. Further, the substrate processing system 50 may be configured to be movable. The substrate processing system 50 may be moved to the power transmitter 140b so that the power transmitter 140b and the power receiver 140a face each other, and power may be supplied to the substrate processing system 50 or each module by supplying power from the power transmitter 140b to the power receiver 140a. The substrate processing system 50 may be configured to automatically move to the power transmitter 140b so that the power transmitter 140b and the power receiver 140a face each other, by receiving a control signal from the outside using a non-contact method such as infrared rays or wireless communication.

According to an embodiment, in the wireless power feeder 140, AC power is supplied from an AC power supply source to the power transmitter 140b. In an embodiment, the power transmitter 140b may convert the frequency using a frequency conversion circuit such as an AC/AC converter and supply AC power to the power receiver 140a. AC power is transmitted from the power transmission coil 144 to the power reception coil 143 by a non-contact means such as magnetic field resonance. Then, a conversion circuit such as an AC/DC converter (not shown) converts the AC power received by the power reception coil 143 into DC power, and supplies the DC power to a member inside the plasma processing chamber 10. Further, in an embodiment, the generated AC power may be supplied as is.

Further, in an embodiment, a power storage that stores electrical power supplied to the power receiver 140a of the substrate processing system 50 may be provided. The power storage may be supplied with DC power by converting AC power into DC power using a conversion circuit such as an AC/DC converter. It may be configured such that electrical power from the power storage is supplied to each module. In addition, each module may have a power storage connected to each module, electrical power supplied to one power receiver may be supplied to the power storage of each of the modules connected in parallel, and the electrical power may be supplied to each module. The capacity of the power storage may be a capacity corresponding to the power usage of each module. Each module may have at least two power storages, and the two or more power storages may be configured to be switchable. By configuring two or more power storages to be switchable, when one power storage fails or electrical power is reduced, it may be switched to another power storage.

As shown in FIG. 3, the above-described substrate processing system 50 is provided with a controller 150. Like the controller 2 described above, the controller 150 may be configured to control each element of the substrate processing system 50 and thereby execute various processes described herein. In an embodiment, part or all of the controller 150 may be included in the substrate processing system 50. For example, like the controller 2, the controller 150 may include a processor 150a1, a memory 150a2, and a communication interface 150a3. The controller 150 is realized by a computer 150a, for example. The processor 150a1 may be configured to read a program from the memory 150a2 and perform various control operations by executing the read program. This program may be previously stored in the memory 150a2, or may be acquired via a medium when necessary. Further, this program may be installed via a network. The acquired program is stored in the memory 150a2, and is read from the memory 150a2 and executed by the processor 150a1. The medium may be any of various storage media that are readable by the computer 150a, or may be a communication line connected to the communication interface 150a3. The processor 150a1 may be a Central Processing Unit (CPU). The memory 150a2 may include a Random Access Memory (RAM), a Read Only Memory (ROM), a Hard Disk Drive (HDD), a Solid State Drive (SSD), or a combination thereof. The communication interface 150a3 may communicate with the plasma processing apparatus 1 via a communication line such as a Local Area Network (LAN).

In the plasma processing system (substrate processing system 50), at least one or both of the wireless power feeder 32 described with reference to FIG. 2 and the wireless power feeder 140 described with reference to FIG. 4 may be provided. Hereinafter, as a configuration according to an embodiment, an example of the electrical power supply system for supplying power to the plasma processing apparatus 1 via the wireless power feeder 32 will be described with reference to the drawings.

### <Electrical Power Supply System>

FIG. 5 is a conceptual diagram showing the schematic configuration of an electrical power supply system S1 according to an embodiment. As shown in FIG. 5, the electrical power supply system S1 includes an AC power source 200 as factory power (factory power source, AC power supply source), and a power transmission coil 34 to which AC power is supplied from the AC power source 200. The power transmission coil 34 is included in the power transmitter 32b, and the power receiver 32a including the power reception coil 33 is provided to face the power transmitter 32b. In the power transmitter 32b, AC power is transmitted from the power transmission coil 34 to the power reception coil 33 by a non-contact means such as a magnetic field resonance method. As a result, electrical power is transferred from the power transmitter 32b to the power receiver 32a.

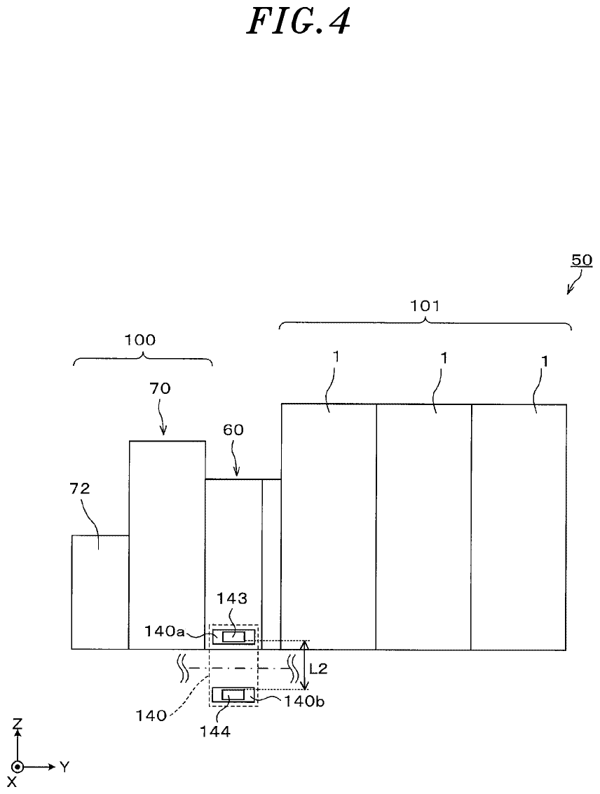

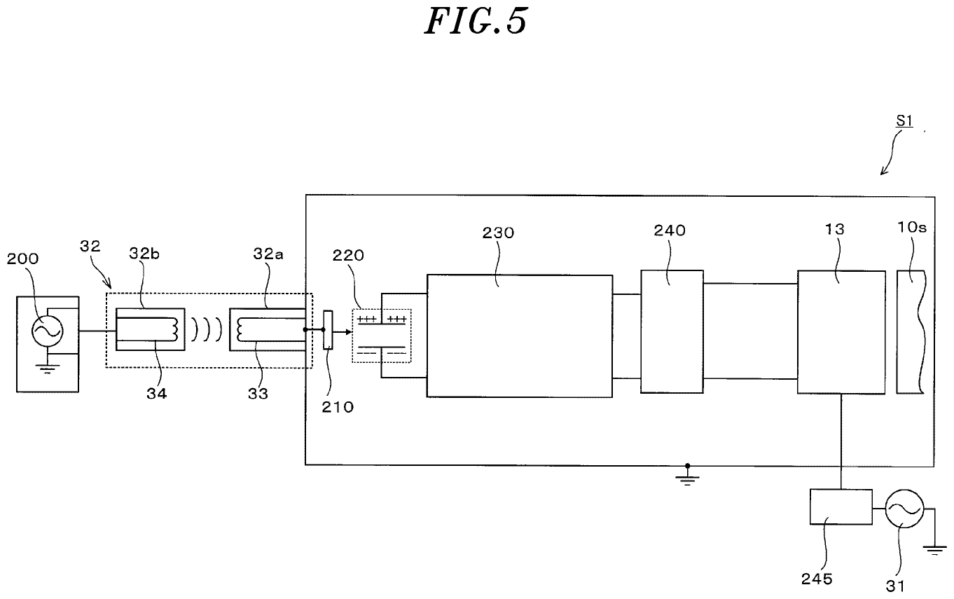

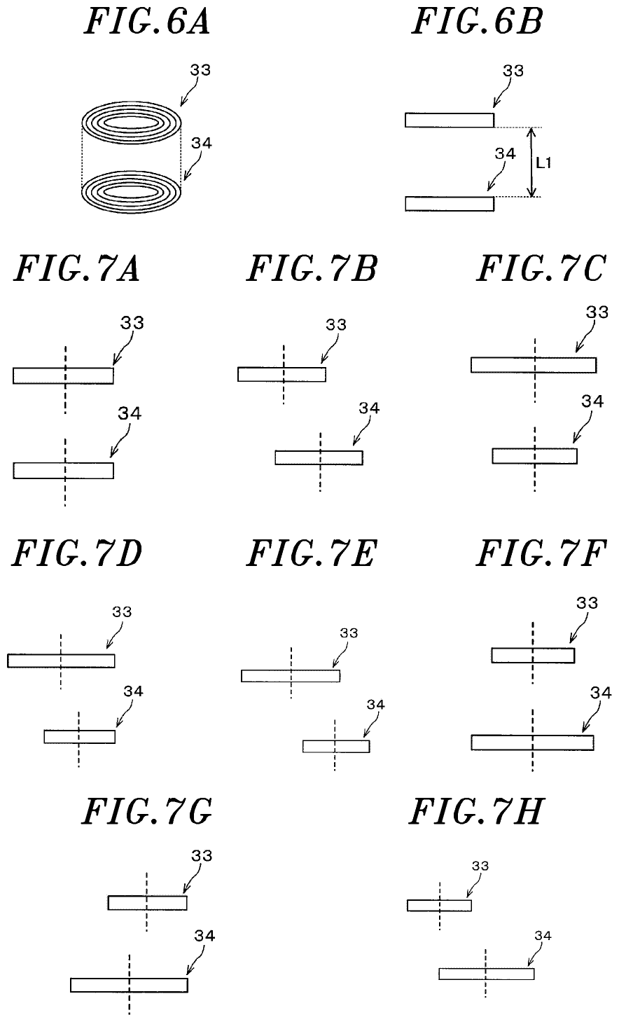

FIGS. 6A and 6B are schematic explanatory diagrams regarding the arrangement relationship between the power transmission coil 34 and the power reception coil 33, where FIG. 6A is a perspective view and FIG. 6B is a side view. As shown in FIGS. 6A and 6B, the expression “the power transmission coil 34 faces the power reception coil 33” means that the opposing surfaces of the coils are located substantially parallel to each other. For example, the separation distance L1 is a distance between the opposing surfaces of the two coils, as shown in FIG. 6B.

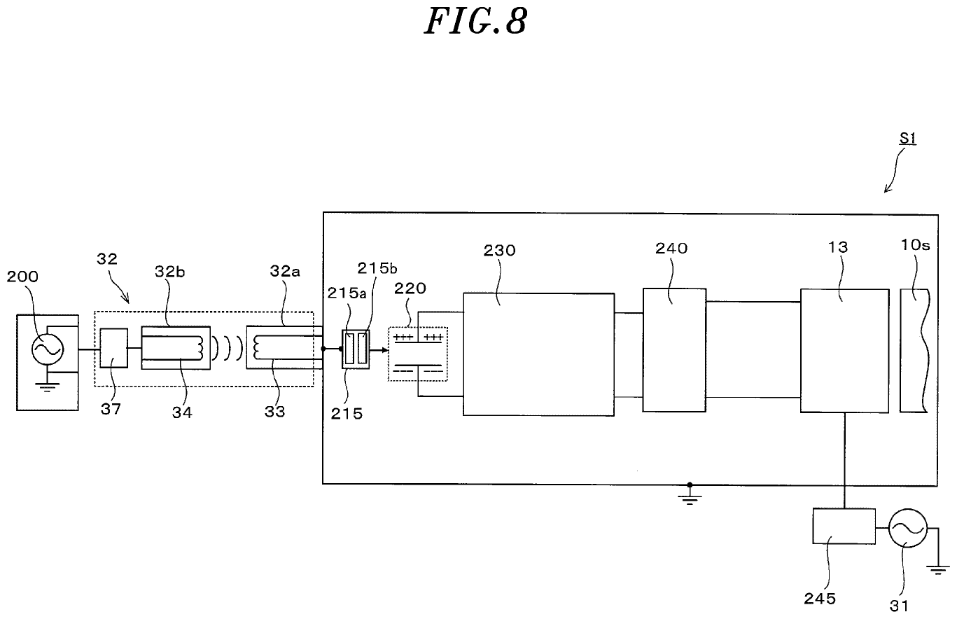

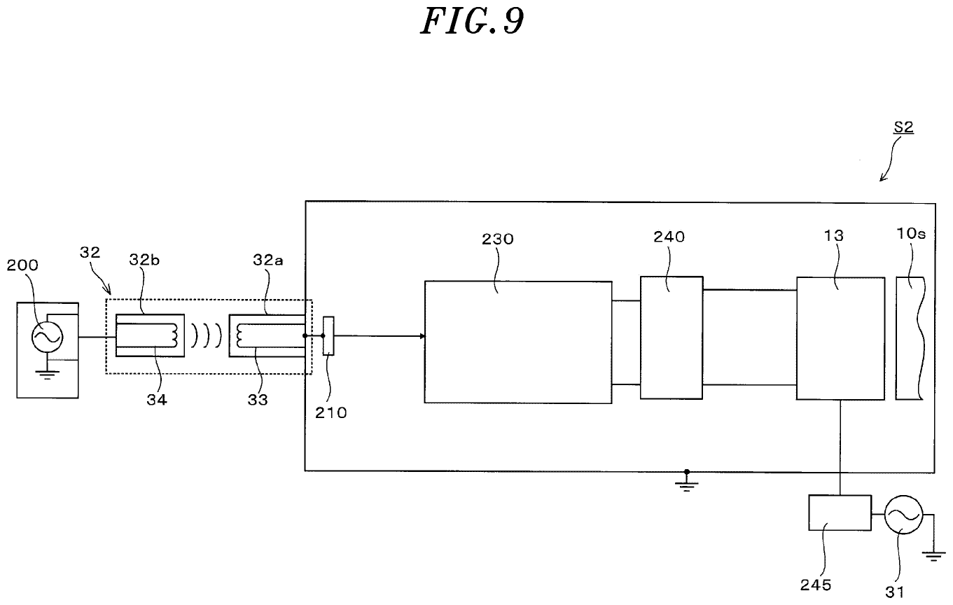

Here, the “facing” of the two coils refers to an arrangement relationship in which the opposing surfaces of the coils are located parallel to each other. Further, each coil may not necessarily have the same size. FIGS. 7A to 7H are schematic explanatory diagrams showing the opposing relationship between coils, for example, the power transmission coil 34 and the power reception coil 33, and examples thereof are listed in FIG. 7A to 7H. In FIGS. 7A to 7H, a coil central axis is shown by a broken line. As shown in FIGS. 7A to 7H, there are various possible configurations of the power transmission coil 34 and the power reception coil 33. For example, two coils are of the same size as shown in FIGS. 7A and 7B, and in the plan view, the entire opposing surfaces overlap each other and the central axes of the coils are substantially coincident with each other in FIG. 7A, and the opposing surfaces partially overlap each other in FIG. 7B. Further, as shown in FIGS. 7C to 7E, among the two coils, the power reception coil 33 is larger than the power transmission coil 34, and in the plan view, the entire opposing surface of the power transmission coil is within the opposing surface of the power reception coil and the central axes of the coils are substantially coincident with each other in FIG. 7C, the entire opposing surface of the power transmission coil is within the opposing surface of the power reception coil but the central axes of the coils are not coincident with each other in FIG. 7D, and a part of the opposing surface of the power transmission coil is outside the opposing surface of the power reception coil in FIG. 7E. Further, as shown in FIGS. 7F to 7H, among the two coils, the power transmission coil 34 is larger than the power reception coil 33, and in the plan view, the entire opposing surface of the power reception coil is within the opposing surface of the power transmission coil and the central axes of the coils are substantially coincident with each other in FIG. 7F, the entire opposing surface of the power reception coil is within the opposing surface of the power transmission coil but the central axes of the coils are not coincident with each other in FIG. 7G, and a part of the opposing surface of the power reception coil is outside the opposing surface of the power transmission coil in FIG. 7H. Any of the configurations of FIGS. 7A to 7H may be taken. However, it is preferable that the entire opposing surfaces of the two coils overlap each other in the plan view and the central axes of the coils substantially coincide with each other, as in FIGS. 7A, 7C, and 7F, for the purpose of power transmission efficiency.

In an embodiment, the power receiver 32a is electrically connected to a capacitor element 220 as the power storage via a converter 210 as a conversion part that converts AC power into DC power. That is, the AC power transmitted to the power receiver 32a is converted into DC power via the converter 210, transmitted to the capacitor element 220 connected to an output side, and stored. A voltage control converter 230 adjusting the DC voltage from the capacitor element 220 is connected to the output side of the capacitor element 220. Further, a constant voltage controller 240 is electrically connected to the voltage control converter 230. In addition, the DC/AC converter may be connected to the output side of the capacitor element 220 to supply AC power to an AC power demand member. In this case, the frequency of the AC power received by the power receiver 32a and the frequency of the AC power output by the DC/AC converter may be equal to or different from each other. Although the capacitor element 220 is illustrated as an example of a means for storing electrical power, a battery may be used for example.

In an embodiment, the shower head 13 including the upper electrode is electrically connected to the constant voltage controller 240. That is, the electrical power output from the capacitor element 220 is controlled to a desired voltage by the voltage control converter 230, and is controlled to a constant voltage by the constant voltage controller 240 to be supplied to the shower head 13.

As described above with reference to FIG. 2, the RF power source 31 is electrically connected to the shower head 13 including the upper electrode. The RF power source 31 is connected to at least one lower electrode and/or at least one upper electrode, the RF signal is supplied, and plasma is formed from at least one processing gas supplied to the plasma processing space 10s. One or more source RF signals from the RF power source 31 are supplied to at least one lower electrode and/or at least one upper electrode via a matcher 245. Accordingly, RF noise generated from the RF power source 31 may propagate to the power receiver 32a via the shower head 13, the constant voltage controller 240, the voltage control converter 230, the capacitor element 220, and the like that are electrically connected to the RF power source 31.

In the electrical power supply system S1 according to this embodiment, the AC power source 200 and the plasma processing apparatus 1 are physically separated from each other with the power reception coil 33 and the power transmission coil 34 interposed therebetween. Impedance between the power reception coil 33 and the power transmission coil 34 is set to be high for frequencies other than the frequency of the transmitted AC power. Therefore, the configuration is such that the frequencies other than the frequency of the transmitted AC power are filtered. For example, when the magnetic resonance method is used, the frequency of the AC power is a resonance frequency (also referred to as a resonant frequency). Therefore, as described above, RF noise generated from the RF power source 31 may be prevented from propagating to the AC power source 200. The frequency of the AC power may have a predetermined bandwidth with the frequency of the AC power as the center frequency.

The electrical power supply system S1 according to this embodiment may include a frequency conversion circuit 37 that converts the frequency of AC power supplied from the AC power source 200 into a frequency suitable for transmission from the wireless power feeder 32. The frequency conversion circuit 37 is an AC/AC converter, for example. FIG. 8 is a conceptual diagram showing a schematic configuration when the frequency conversion circuit is included in the electrical power supply system S1 according to this embodiment.

As shown in FIG. 8, in an embodiment, the wireless power feeder 32 includes the frequency conversion circuit 37 that converts the frequency of AC power supplied from the AC power source 200 into a transmission frequency. In the frequency conversion circuit 37, the frequency supplied from the AC power source 200, the frequency of the AC power having 50 Hz or 60 Hz is converted into a transmission frequency of a sine wave or a square wave having the frequency of 85 kHz to 250 kHz, for example. When converted into the square wave, the sine wave converted by the frequency conversion circuit is converted into the square wave by a conversion circuit (not shown).

According to such a configuration, when AC power is transmitted from the power transmission coil 34 to the power reception coil 33 by a non-contact means such as a magnetic field resonance method, the frequency is converted by the frequency conversion circuit 37 and then is transmitted. This makes it possible to use a frequency suitable for transmission and efficiently transmit power by the non-contact means.

In an embodiment, the electrical power sent to the power receiver 32a is transmitted through a rectifying and smoothing part 215 to the capacitor element 220 connected to an output side thereof and is stored therein. The rectifying and smoothing part 215 includes a rectifying circuit 215a and a smoothing circuit 215b. The rectifying circuit 215a includes, for example, a bridge diode or the like. The smoothing circuit 215b includes a capacitor, a low-pass filter, etc. In the example of FIG. 8, the rectifying circuit 215a rectifies the AC signal received by the power receiver 32a in a forward direction (positive direction) using the bridge diode, for example. The output signal of the rectifying circuit 215a generally becomes a pulsating current. Therefore, the output signal of the rectifying circuit 215a is input into the smoothing circuit 215b, and the pulsating current is converted into DC power of a voltage suitable for the capacitor element 220. The rectifying and smoothing part 215 may measure the electrical power stored in the capacitor element 220, and may control power transmission and reception in the wireless power feeder 32 based on the measured result. In the rectifying circuit 215a, the AC signal received by the power receiver 32a may be rectified in a reverse direction (negative direction) using the bridge diode, for example.

### Effects of the Technology of the Present Disclosure

In the electrical power supply system S1 according to this embodiment, when supplying electrical power from the AC power source 200 to the plasma processing apparatus 1, a configuration using the wireless power feeder 32 including the power transmitter 32b and the power receiver 32a that are physically separated from each other is adopted. Likewise, in the substrate processing system 50, a configuration using the wireless power feeder 140 including the power transmitter 140b and the power receiver 140a is adopted. Thereby, the connection wiring between the plasma processing apparatus 1 or the substrate processing system 50 and the AC power source 200, or the connection wiring in the periphery thereof may be reduced or eliminated. Therefore, wiring confusion can be prevented, and wiring installation or removal work can be simplified when installing or removing the apparatus. In addition, this can reduce equipment costs, simplify equipment design, and expand space.

Further, in the plasma processing apparatus 1 in which the RF power source 31 is connected to at least one lower electrode and/or at least one upper electrode, the AC power source 200 and the plasma processing apparatus 1 are physically separated from each other, thereby preventing the RF noise from propagating to the AC power source 200. Since it is unnecessary to provide a filter that cuts RF noise, it is possible to suppress bias in the process due to variations in the filter performance and guarantee uniformity. Further, it is possible to improve power efficiency.

Further, in the electrical power supply system S1, when power is supplied from the AC power source 200 to the plasma processing apparatus 1, the electrical power is stored in the capacitor element 220. Then, by supplying electric charge from the capacitor element 220, a member using the DC power in the plasma processing apparatus 1 is driven. Therefore, by adjusting the capacitance of the capacitor element 220, it is possible to limit the supply amount of charge, prevent excessive current during arcing (abnormal discharge), and suppress damage to a member.

It should be noted that the embodiments disclosed herein are illustrative in all respects but are not restrictive. The embodiments described above may be omitted, substituted, or modified in various forms without departing from the scope and spirit of the appended claims.

For example, in the electrical power supply system S1 described in the above embodiment, a case is illustrated in which the shower head 13 including the upper electrode is electrically connected to the constant voltage controller 240. Further, as the member that is electrically connected to the RF power source 31, the shower head 13 including the upper electrode is illustrated. However, the application scope of the present disclosure is not limited thereto.

It may be at least one of the substrate processing system, substrate processing apparatus, unit or member using DC power. In the present disclosure, the substrate processing system includes a plurality of substrate processing apparatuses. The substrate processing system 50 of this embodiment is exemplified as the substrate processing system, and the plasma processing apparatus 1 of this embodiment is exemplified as the substrate processing apparatus. Further, in the present disclosure, the unit is a combination of a plurality of members, and the unit and members may be provided inside or outside the substrate processing apparatus. For example, inside the plasma processing apparatus 1, the base 1110 or the electrostatic chuck 1111 is exemplified as the member, and the main body 111 or the substrate support 11 is exemplified as the unit. Outside the plasma processing apparatus 1, the transfer arm 91 is exemplified as the member, and the substrate transfer device 90 is exemplified as the unit.

The wireless power supply of the present disclosure includes the following cases.
(1) a case where power is supplied to the substrate processing system itself.
(2) a case where power is supplied to the substrate processing apparatus itself.
(3) a case where power is supplied to the unit inside the substrate processing apparatus.
(4) a case where power is supplied to the member inside the substrate processing apparatus.
(5) a case where power is supplied to the unit inside the substrate processing system and outside the substrate processing apparatus.
(6) a case where power is supplied to the member inside the substrate processing system and outside the substrate processing apparatus.

As described above, the target of the present disclosure includes all units or members in addition to the substrate processing system 50 and the plasma processing apparatus 1 operated using electric power, regardless of AC or DC. A specific example will be described below. For example, the following are exemplified as the members constituting the plasma processing chamber 10 and its surrounding members. They may be a matcher electrically connected to an ICP antenna, a variable capacitor attached to an absorption coil, a motor for driving a gap between the upper electrode and the lower electrode, or the ICP antenna. Further, they may be an upper electrode, a matcher for upper RF, or a suction mechanism for the upper electrode. Further, they may be an electrode included in an electrostatic chuck, an actuator for driving a lifting pin, a matcher for a lower RF, a DC pulse electrode, a controller and a cooling fan for a resistance heater, an inductive heater, a ceramic member suction mechanism for replacing ceramic members, or a motor for driving a stage. Further, they may be an edge ring, a power source for controlling an edge ring potential, a pin for driving the edge ring, an electrode for adsorbing the substrate or the edge ring, a variable capacitor a variable inductor, and a variable resistor for impedance control, a motor for a relay, a coil, and a DC electrode. Further, they may be a resistance heater disposed on the side wall of the chamber, a controller for the resistance heater, a DC electrode disposed on the side wall of the chamber, or an inductive heater. Further, they may be a distance sensor, a film thickness sensor, a camera, a wafer-embedded sensor, a luminescence sensor, or a quadrupole mass spectrometer (Q-MASS). Further, they may be a controller for an external coil (electromagnet) or a controller for an internal coil. Alternatively, they may be a resistance heater, an inductive heater, a gas valve, or a flowmeter included in a gas box. Further, they may be a motor of a pressure regulating valve, a turbo molecular pump, a dry pump, a resistance heater in piping, or an inductive heater.

Further, the following is exemplified as members located upstream of the plasma processing chamber 10. They may be an AC power box, a gas box, or a chiller. Further, they may be a transfer arm for a transfer module, a sensor, a turbo molecular pump, a dry pump, a motor for a drive pin in the load lock module, a heater, a position sensor, a motor for an arm, a motor for an orienter, a valve for N₂ circulation, a motor for a load port shutter, a sensor, or an N₂ valve for purge storage.

Although a case where the electrical power supply system S1 includes the voltage control converter 230 or the constant voltage controller 240 is illustrated and described, they are not necessarily essential components. That is, in an embodiment, when a target member to which electrical power is supplied is a member that does not require voltage control, such as various heaters, the system may be configured not to include the voltage control converter 230 or the constant voltage controller 240.

### Other Embodiments of the Present Disclosure

In the above embodiment, although the case where electrical power sent to the power receiver 32a in the electrical power supply system S1 is transmitted through the converter 210 to the capacitor element 220 connected to the output side thereof and stored therein is illustrated and described, the disclosed technology is not limited thereto. Other embodiments of the present disclosure will be described below with reference to FIG. 9. In FIG. 9, components having the same functional configuration as the above embodiment are denoted by the same reference numerals, and a description thereof will be omitted.

FIG. 9 is a conceptual diagram showing a schematic configuration of an electrical power supply system S2 according to another embodiment. As shown in FIG. 9, the basic configuration of the electrical power supply system S2 remains the same as the electrical power supply system S1 according to the above embodiment. However, the electrical power supply system S2 has a configuration that does not include the capacitor element 220 as the power storage. That is, the power receiver 32a of the wireless power feeder 32 is electrically connected to the voltage control converter 230 via the converter 210.

AC power supplied from the AC power source 200 is transferred to the power receiver 32a through the power transmitter 32b, and electrical power transmitted to the power receiver 32a is transmitted through the converter 210 to the voltage control converter 230 connected to the output side thereof. The constant voltage controller 240 is electrically connected to the voltage control converter 230. That is, electrical power transferred from the AC power source 200 via the wireless power feeder 32 is converted into DC power in the converter 210, controlled to a desired voltage by the voltage control converter 230, and further controlled to a constant voltage by the constant voltage controller 240, and then supplied to the shower head 13.

In the electrical power supply system S2 configured as shown in FIG. 9, when supplying electrical power from the AC power source 200 to the plasma processing apparatus 1, a configuration using the wireless power feeder 32 including the power transmitter 32b and the power receiver 32a that are physically separated from each other is adopted. Thereby, the connection wiring between the plasma processing apparatus 1 or the substrate processing system 50 and the AC power source 200, or the connection wiring in the periphery thereof may be reduced or eliminated. Therefore, wiring confusion can be prevented, and wiring installation or removal work can be simplified when installing or removing the apparatus. In addition, this can reduce equipment costs and expand space.

Further, in the plasma processing apparatus 1 in which the RF power source 31 is connected to at least one lower electrode and/or at least one upper electrode, the AC power source 200 and the plasma processing apparatus 1 are physically separated from each other, thereby preventing the RF noise from propagating to the AC power source 200. Since it is unnecessary to provide a filter that cuts RF noise, it is possible to suppress bias in the process due to variations in the filter performance and guarantee uniformity. Further, it is possible to improve power efficiency.

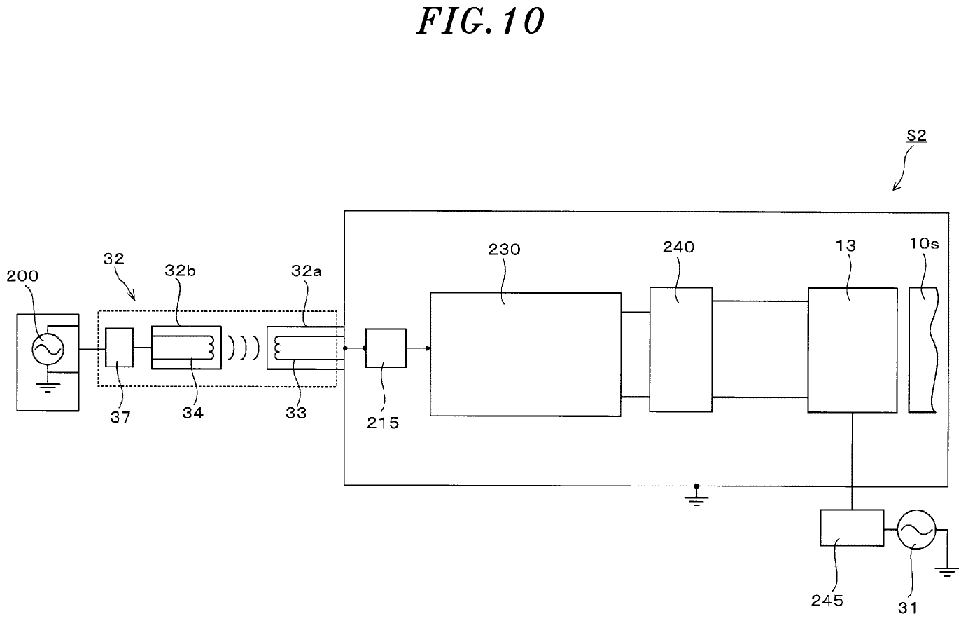

The electrical power supply system S2 shown in FIG. 9 may include a frequency conversion circuit 37 that converts the frequency of AC power supplied from the AC power source 200 into a frequency suitable for transmission from the wireless power feeder 32, as in the configuration in FIG. 8 of the above embodiment. FIG. 10 is a conceptual diagram showing a schematic configuration when the frequency conversion circuit is included in the electrical power supply system S2.

In the configuration shown in FIG. 10, the frequency conversion circuit 37 converts and transmits the frequency. This makes it possible to use a frequency suitable for transmission and efficiently transmit electrical power by a non-contact means. Further, in an embodiment, when power is transmitted from the power receiver 32a to the voltage control converter 230, the power may pass through the rectifying and smoothing part 215.

### Reference Example

Further, in order to appropriately supply electrical power to the substrate processing apparatus, a substrate processing apparatus and a substrate processing method as shown in the following reference example may be provided. In this reference example, elements having substantially the same functional configuration as those described in the above or other embodiments may be designated by the same reference numerals, so that a duplicated description thereof will be omitted herein.

In the manufacturing process of a semiconductor device, various substrate processes are performed in which the interior of a processing module accommodating a semiconductor substrate (hereinafter also simply referred to as a “substrate”) is brought into a reduced pressure state and the substrate is subjected to a predetermined process. For example, plasma processing is performed by mounting the substrate on the substrate support in the processing container, heating the substrate support, and generating plasma in the processing container using the RF electrical power.

When heating the substrate support, AC power is supplied to the heater from, for example, an alternating current (hereinafter simply referred to as AC) power supply source in a factory. However, when performing plasma processing by generating plasma in the processing container using the RF electrical power, RF noise may reach the AC power supply source through a power supply path via the substrate support, thereby adversely affecting the AC power supply source. Therefore, JP Patent Publication No. 2015-173027 discloses technology for attenuating or blocking the RF noise using the filter.

However, if a so-called RF filter that attenuates or blocks the RF noise is interposed in the power supply path, power to be supplied may be attenuated due to the presence of the RF filter, and the planned power may not be input to the heater. Further, RF filters are required as many as power supply targets, and there is a possibility that space for arranging the RF filters is not secured within the apparatus.

This reference example has been made in view of the above circumstances, and provides technology that can easily take measures against RF noise reaching the AC power supply source though the power supply path via, for example, the substrate support, without using the above-mentioned RF filter. In this reference example, power is efficiently supplied to the unit or member using the electrical power in the substrate processing apparatus. Further, this reference example can save space in the apparatus.

Hereinafter, a plasma processing apparatus as the substrate processing apparatus according to an embodiment of this reference example will be described with reference to the drawings. In the following reference example and drawings, elements having substantially the same functional configuration are designated by the same reference numerals, so that a duplicated description thereof will be omitted herein.

### <Plasma Processing System>

Since the configuration of the plasma processing system having the plasma processing apparatus 1 (referred to as 1a in the following reference example) as an example of the substrate processing apparatus according to this reference example is the same as that described with reference to FIG. 1 in the above embodiment, a description thereof will be omitted herein.

### <Plasma Processing Apparatus>

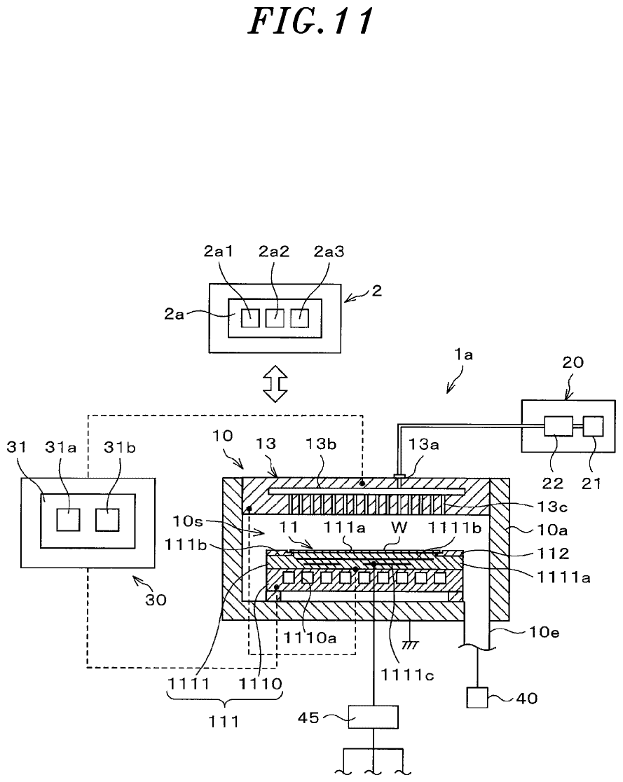

Hereinafter, a configuration example of a capacitively coupled plasma processing apparatus as an example of the plasma processing apparatus 1a will be described. FIG. 11 is a diagram for explaining the configuration example of the capacitively coupled plasma processing apparatus 1a. In FIG. 11, components common to the apparatus configuration described above with reference to FIG. 2 are denoted by the same reference numerals, and a description thereof will be omitted herein.

In an embodiment, the flow path 1110a is formed in the base 1110. In an example, one or more heaters 1111c are disposed in the ceramic member 1111a of the electrostatic chuck 1111. The heater 1111c generates heat when DC power is supplied. DC power is supplied from the power storage 45 to the heater 1111c.

### <Substrate Processing System>

Further, the substrate processing system 50, which is an example of a specific configuration of the plasma processing system including the above-described plasma processing apparatus 1a, has basically the same configuration as that described with reference to FIG. 3 in the above embodiment. Therefore, the description of the substrate processing system 50 will be omitted herein.

### <Electrical Power Supply System of Substrate Processing Apparatus>

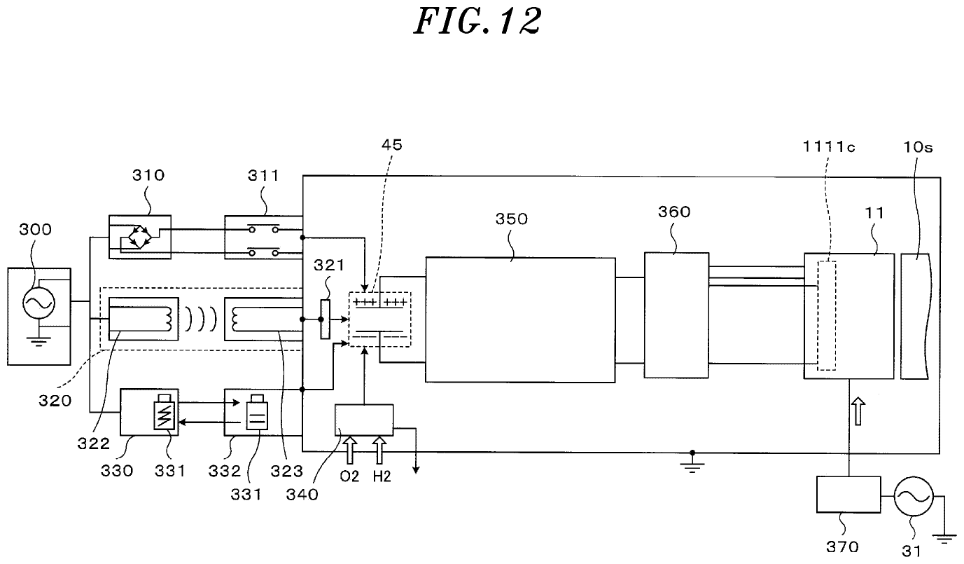

FIG. 12 is a conceptual diagram showing a schematic configuration of the electrical power supply system of the plasma processing apparatus 1a as the substrate processing apparatus according to an embodiment. As shown in FIG. 12, in this example, AC power from the AC power source 300 as factory power (factory power source, AC power supply source) is converted into DC power, and the unit using the DC power, for example, the heater 1111c as the member is supplied with DC power via the power storage 45. The heater 1111c is one or more heaters provided in the electrostatic chuck 1111. The power storage 45 may be any device as long as it may store the supplied DC power, and may use a capacitor element or a battery, for example. The capacitor element and the battery may be used together. The internal (parasitic) resistance of the capacitor element is preferably small, for example, 100 mΩ or less. When power is supplied to a plurality of heaters, this configuration eliminates the need for the RF filter for each heater.

In the example shown in FIG. 12, four DC power supply systems to the power storage 45 are prepared. First, in a first supply system, AC power is supplied from the AC power source 300 to the AC/DC converter 310 and is converted into DC power. Thereafter, the DC power is supplied to the power storage 45 via the relay 311.

In a second supply system, DC power is supplied from the AC power source 300 to the wireless power feeder 320, and then supplied from the AC/DC converter 321 to the power storage 45. That is, the wireless power feeder 320 includes a power transmission coil 322 to which AC power is supplied from the AC power source 300, and a power reception coil 323 disposed to face the power transmission coil 322. Further, when AC is supplied to the power transmission coil 322, AC is output from the power reception coil 323 in a non-contact manner, for example, a magnetic field resonance method, an electromagnetic coupling method, an electromagnetic induction method, or the like. The power transmission coil 322 and the power reception coil 323 are physically separated. The separation distance may be a distance where the propagation of RF noise may be suppressed and electrical power may be supplied, for example, 1 mm or more and 200 mm or less, preferably 5 mm or more and 150 mm or less, and more preferably 10 mm or more and 100 mm or less. After AC power from the power reception coil 323 is converted into DC power by the AC/DC converter 321, the DC power is supplied to the power storage 45.

In a third supply system, AC power is supplied from the AC power source 300 to a charger 330, and is converted into DC power by the AC/DC converter (not shown) in the charger 330 to charge the rechargeable battery 331. The charged battery 331 is set in an output part 332, so that DC power is supplied from the output part 332 to the power storage 45.

The fourth supply system supplies DC power generated from a fuel cell 340 to the power storage 45. As oxygen and hydrogen that are raw materials for the fuel cell 340, it is possible to use, for example, oxygen and hydrogen supplied to various semiconductor manufacturing apparatuses in a facility where the plasma processing apparatus 1a is installed, such as a clean room. Further, the fuel cell 340 may be disposed in the plasma processing apparatus 1a.

The electric charges stored by the DC power supplied to the power storage 45 are supplied as DC power to the constant voltage controller 360 via the voltage control converter 350 that adjusts the DC voltage. The DC power from the constant voltage controller 360 is supplied to the heater 1111c provided in the substrate support 11. Further, the DC/AC converter may be connected to the output side of the power storage 45 to supply AC power to the AC power demand member. In this case, the frequency of the AC power received by the power reception coil 323 and the frequency of the AC power output by the DC/AC converter may be equal to or different from each other.

RF electrical power is supplied from the above-described RF power source 31 through the matcher 370 to the substrate support 11 including the lower electrode.

### Effects of the Technology of this Reference Example

In the plasma processing apparatus 1a according to this reference example, the electric charge stored in the power storage 45 is supplied as DC to the heater 1111c that operates using the DC power, so that it is possible to easily suppress the RF noise generated in the power supply system during plasma processing without using the RF filter.

That is, during plasma processing, RF noise generated from the RF power source 31 propagates from the substrate support 11 electrically connected to the RF power source 31 via the heater 1111c, the constant voltage controller 360, the voltage control converter 350, and the power storage 45.

However, since DC power is supplied from the power storage 45 to the heater 1111c, the power storage 45 itself does not need to be directly connected to another power source, for example, the AC power source 300 even while the heater 1111c is operating during plasma processing. Therefore, the means for suppressing the propagation of RF noise to the AC power source 300 can be easily adopted.

That is, in the first supply system, the power storage 45 and the AC power source 300 are connected via the relay 311, so that it is possible to suppress the propagation of the RF noise to the AC power source 300 by cutting off the relay 311 during plasma processing. Then, while plasma processing is not being performed, the relay 311 may be energized to supply electric charge to the power storage 45.

In the second supply system, since DC power is supplied from the AC power source 300 through the wireless power feeder 320 to the power storage 45, the propagation of RF noise from the power receiver to the power transmitter is suppressed.

In the third supply system, since DC power is supplied from the rechargeable battery 331 to the power storage 45, it is unnecessary to consider the propagation of RF noise from the power storage 45 to the AC power source 300 at first.

Since the fourth supply system supplies DC power generated from the fuel cell 340 to the power storage 45, it is unnecessary to consider the propagation of RF noise from the power storage 45 to the AC power source 300 at first.

Since the configuration is such that DC power is supplied from the power storage 45, as shown in the first to fourth supply systems, it is possible to easily employ a plurality of means for suppressing the propagation of the RF noise to the AC power source 300 without using the RF filter.

Since it is unnecessary to provide the RF filter for suppressing the propagation of RF noise to the AC power source 300 in the power supply path from the power storage 45 to the heater 1111c, power can be efficiently input from the power storage 45 to the heater 1111c. Since it is unnecessary to provide the filter that cuts RF noise, it is possible to suppress bias in the process due to variations in the filter performance and guarantee uniformity.

In the above-mentioned reference example, the configuration includes all of the first to fourth supply systems, but may include at least one of the four supply systems.

Furthermore, by employing the combination of a plurality of supply systems, the battery 331 can be charged during plasma processing, and the duration of the power storage 45 can be extended by supplying DC power to the power storage 45 using the fuel cell 340.

As oxygen and hydrogen that are raw materials for the fuel cell 340, it is possible to use, for example, oxygen and hydrogen supplied to various semiconductor manufacturing apparatuses in a facility where the plasma processing apparatus 1a is installed, such as a clean room.

It should be noted that the embodiments disclosed herein are illustrative in all respects but are not restrictive. The embodiments described above may be omitted, substituted, or modified in various forms without departing from the scope and spirit of the appended claims.

For example, in the plasma processing apparatus 1a described in the above reference example, DC power is supplied from the power storage 45 to the heater 1111c, but a demand part for supplying DC power from the power storage 45 is not limited thereto. In other words, technology according to this reference example may be applied to any unit or member that uses DC in the substrate processing apparatus or the substrate processing system.

That is, according to this reference example, the unit is a combination of a plurality of members, and the unit and members may be provided inside or outside the substrate processing apparatus. For example, inside the plasma processing apparatus 1a, the base 1110 or the electrostatic chuck 1111 is exemplified as the member, and the main body 111 or the substrate support 11 is exemplified as the unit. Outside the plasma processing apparatus 1a, the transfer arm 91 is exemplified as the member, and the substrate transfer device 90 is exemplified as the unit.

The member targeted by this reference example may be any member operated using electric power, regardless of AC or DC. A specific example will be described below. For example, the following are exemplified as the members constituting the plasma processing chamber 10 and its surrounding members. They may be a matcher electrically connected to an ICP antenna, a variable capacitor attached to an absorption coil, a motor for driving a gap between the upper electrode and the lower electrode, or the ICP antenna. Further, they may be an upper electrode, a matcher for upper RF, or a suction mechanism for the upper electrode. Further, they may be an electrode included in an electrostatic chuck, an actuator for driving a lifting pin, a matcher for a lower RF, a DC pulse electrode, a controller and a cooling fan for a resistance heater, an inductive heater, a ceramic member suction mechanism for replacing ceramic members, or a motor for driving a stage. Further, they may be an edge ring, a power source for controlling an edge ring potential, a pin for driving the edge ring, an electrode for adsorbing the substrate or the edge ring, a variable capacitor a variable inductor, and a variable resistor for impedance control, a motor for a relay, a coil, and a DC electrode. Further, they may be a resistance heater disposed on the side wall of the chamber, a controller for the resistance heater, a DC electrode disposed on the side wall of the chamber, or an inductive heater. Further, they may be sensors, such as a distance sensor, a film thickness sensor, a camera, a wafer-embedded sensor, a luminescence sensor, or a quadrupole mass spectrometer (Q-MASS). Further, they may be a controller for an external coil (electromagnet) or a controller for an internal coil. Alternatively, they may be a resistance heater, an inductive heater, a gas valve, or a flowmeter included in a gas box. Further, they may be a motor of a pressure regulating valve, a turbo molecular pump, a dry pump, a resistance heater in piping, or an inductive heater.

Further, the following is exemplified as members located upstream of the plasma processing chamber 10. They may be an AC power box, a gas box, or a chiller. Further, they may be a transfer arm for a transfer module, a sensor, a turbo molecular pump, a dry pump, a motor for a drive pin in the load lock module, a heater, a position sensor, a motor for an arm, a motor for an orienter, a valve for N₂ circulation, a motor for a load port shutter, a sensor, or an N₂ valve for purge storage.

Although a case including the voltage control converter 350 or the constant voltage controller 360 is illustrated and described in the reference example, they are not necessarily essential components. That is, in an embodiment, when a target member to which electrical power is supplied is a member that does not require voltage control, the apparatus may be configured not to include the voltage control converter 350 or the constant voltage controller 360.

Further, in this reference example, the frequency conversion circuit may be provided between the AC power source 300 and the power transmission coil 322. According to such a configuration, when AC power is transmitted from the power transmission coil 322 to the power reception coil 323 by a non-contact means such as a magnetic field resonance method, the frequency is converted by the frequency conversion circuit and then is transmitted. This makes it possible to use a frequency suitable for transmission and efficiently transmit power by the non-contact means. According to the reference example, the rectifying and smoothing part may be provided instead of the AC/DC converter 321. The rectifying and smoothing part includes, for example, a bridge diode, a capacitor, a low-pass filter, and the like. In the rectifying and smoothing part, a negative voltage side of AC input is inverted by, for example, the bridge diode, and the inverted output is smoothed by the capacitor or the low-pass filter to be stored in the power storage 45 as the DC power at a voltage suitable for the capacitor element, for example.

### APPENDICES

### Appendix 1

A substrate processing apparatus, comprising:
a power storage,
at least one of a unit or a member using power,
wherein electric charge stored in the power storage is supplied to the unit or member as electrical power.

### Appendix 2

The substrate processing apparatus of Appendix 1, wherein the apparatus includes a power reception coil that receives power in a non-contact manner from a power transmission coil supplied with power from an AC power supply source, and
a conversion part that convers AC power from the power reception coil into DC power is connected to the power storage.

### Appendix 3

The substrate processing apparatus of Appendix 1, wherein the apparatus comprises a controller,
the controller is configured to convert power from an AC power supply source into DC power and supply it to the power storage, and
the controller is configured to electrically disconnect the power storage from the AC power supply source during substrate processing using RF power in the substrate processing apparatus.

### Appendix 4

The substrate processing apparatus of Appendix 3, wherein the controller is configured to convert power from the AC power supply source into the DC power and then supply the converted power to the power storage through an electrical supply path,
the electrical supply path is provided with a relay, and
the relay is in a cut off state when substrate processing using RF power in the substrate processing apparatus.

### Appendix 5

The substrate processing apparatus of Appendix 2, comprising:
a frequency conversion circuit that converts a frequency of power supplied from the AC power supply source into a transmission frequency and transmits it, and
a rectifying circuit and a smoothing circuit that rectify and smooth the electrical power after frequency conversion by the frequency conversion circuit and then supply the power to the power storage.

### Appendix 6

The substrate processing apparatus of Appendix 1, wherein power is supplied to the power storage by supplying DC power from a battery.

### Appendix 7

The substrate processing apparatus of Appendix 6, wherein the battery is charged by converting power from the AC power supply source into DC power and supplying the DC power.

### Appendix 8

The substrate processing apparatus of Appendix 1, further comprising a power generation mechanism, wherein power is supplied to the power storage by supplying power obtained by the power generation mechanism.

### Appendix 9

The substrate processing apparatus of Appendix 8, wherein the power generation mechanism uses fuel cell power generation.

### Appendix 10

The substrate processing apparatus of Appendix 9, wherein at least one of oxygen or hydrogen used in the fuel cell power generation is used to process the substrate at a facility in which the substrate processing apparatus is installed.

### Appendix 11

The substrate processing apparatus of any one of Appendices 1 to 10, wherein a plurality of power storages are provided, and each power storage is connected in parallel to the unit or member, and
when a voltage of one of the plurality of power storages decreases to be lower than a voltage required for the unit or member to which charge stored in the one power storage is supplied as power, the apparatus is configured to switch to supply power from another power storage.

### Appendix 12

The substrate processing apparatus of Appendix 11, wherein, after switching to supply from another power storage, the one power storage with decreased voltage is configured to supply power to a unit or member that is driven even at the decreased voltage.

### Appendix 13

The substrate processing apparatus of Appendix 11, wherein, after switching to supply from another power storage, power is supplied to the one power storage with decreased voltage.

### Appendix 14

The substrate processing apparatus of any one of Appendices 1 to 13, wherein a relatively low capacity power storage having a lower capacity than the power storage is connected in parallel between the unit or member and the power storage.

### Appendix 15

The substrate processing apparatus of Appendix 14, wherein another relatively low capacity power storage having a lower capacity than the relatively low capacity power storage is connected in parallel between the unit or member and the relatively low capacity power storage.

### Appendix 16

The substrate processing apparatus of any one of Appendices 1 to 15, wherein the power storage is a capacitor element or a battery.

### Appendix 17

The substrate processing apparatus of Appendix 16, wherein an internal resistance of the capacitor element is 100 mΩ or less.

### Appendix 18

A substrate processing method for processing a substrate using a substrate processing apparatus, the substrate processing apparatus including a power storage and at least one unit or member using power, comprising:
supplying charge from the power storage to the unit or member as electrical power.

1. A substrate processing apparatus for processing a substrate, comprising:
a power receiver including a power reception coil to which power is transmitted in a non-contact manner from a power transmission coil located outside the substrate processing apparatus,
wherein the substrate processing apparatus is configured to supply power to at least one unit or member that uses power from the power receiver.

2. The substrate processing apparatus of claim 1, wherein the unit or member that uses power from the power receiver comprises an upper electrode of the substrate processing apparatus.

3. The substrate processing apparatus of claim 1, wherein the unit or member that uses power from the power receiver comprises a lower electrode of the substrate processing apparatus.

4. The substrate processing apparatus of claim 1, further comprising:
a power storage for storing power supplied from the power receiver,
wherein, between the power storage and an AC power supply source that supplies power to the power transmission coil, impedance at frequencies other than a frequency of transmitted AC power is set higher than impedance of the frequency of the transmitted AC power, and
a conversion part that converts AC power from the power reception coil into DC power is connected to the power storage.

5. The substrate processing apparatus of claim 1, further comprising:
a power storage for storing power supplied from the power receiver,
wherein, between the power storage and an AC power supply source that supplies power to the power transmission coil, impedance at frequencies other than a frequency of transmitted AC power is set higher than impedance of the frequency of the transmitted AC power,
a frequency conversion circuit that converts a frequency of power supplied from the AC power supply source to the power transmission coil into a transmission frequency and transmits power, and
a rectifying circuit and a smoothing circuit that rectify and smooth power supplied from the power reception coil to the power storage.

6. The substrate processing apparatus of claim 4, wherein the power storage is a capacitor element or a battery.

7. A substrate processing system having a plurality of substrate processing apparatuses for processing a substrate, comprising:
a power receiver including a power reception coil to which power is transmitted in a non-contact manner from a power transmission coil located outside the substrate processing system,
wherein the system is configured to supply power to at least one of the substrate processing apparatus, a unit or a member that uses power from the power receiver.

8. The substrate processing system of claim 7, further comprising:
a power storage for storing power supplied from the power receiver,
wherein, between the power storage and an AC power supply source that supplies power to the power transmission coil, impedance at frequencies other than a frequency of transmitted AC power is set higher than impedance of the frequency of the transmitted AC power, and
a conversion part that converts AC power from the power reception coil into DC power is connected to the power storage.

9. The substrate processing system of claim 7, further comprising:
a power storage for storing power supplied from the power receiver,
wherein, between the power storage and an AC power supply source that supplies power to the power transmission coil, impedance at frequencies other than a frequency of transmitted AC power is set higher than impedance of the frequency of the transmitted AC power,
a frequency conversion circuit that converts a frequency of power supplied from the AC power supply source to the power transmission coil into a transmission frequency and transmits power, and
a rectifying circuit and a smoothing circuit that rectify and smooth power supplied from the power reception coil to the power storage.

10. The substrate processing system of claim 8, wherein the power storage is a capacitor element or a battery.

11. The substrate processing system of claim 7, wherein the power receiver is disposed on a bottom of the substrate processing system.

12. The substrate processing system of claim 7, wherein the substrate processing system comprises one or more processing modules, a transfer module, a load lock module, and a loader module, and
the power receiver is disposed on a bottom of at least one among the processing modules, the transfer module, the load lock module, and the loader module.

13. The substrate processing system of claim 7, wherein the substrate processing system comprises one or more processing modules, a transfer module, a load lock module, and a loader module,
the power receiver is disposed at least one among the processing modules, the transfer module, the load lock module, and the loader module, and
power supplied to the power receiver is distributed to the processing modules, the transfer module, the load lock module, and the loader module.

14. The substrate processing system of claim 7, wherein the substrate processing system is configured to be movable such that the power receiver included in the substrate processing system faces the power transmission coil.

15. The substrate processing system of claim 14, wherein the substrate processing system is configured to automatically move to face the power transmission coil by receiving an external control signal in a non-contact manner.

16. The substrate processing system of claim 7, wherein the substrate processing system comprises one power receiver and a plurality of power storages connected in parallel to the power receiver, and
power supplied to the one power receiver is configured to be stored in the plurality of power storages.

17. The substrate processing system of claim 16, wherein the substrate processing system comprises one or more processing modules, a transfer module, a load lock module, and a loader module, and
power stored in the plurality of power storages is supplied to each of the processing modules, the transfer module, the load lock module, and the loader module.

18. The substrate processing system of claim 16, wherein capacity of the plurality of power storages corresponds to power usage of the processing modules, the transfer module, the load lock module, and the loader module.

19. The substrate processing system of claim 7, wherein the substrate processing system comprises one or more processing modules, a transfer module, a load lock module, and a loader module, and
each of the processing modules, the transfer module, the load lock module, and the loader module has at least two or more power storages.

20. The substrate processing system of claim 19, wherein the two or more power storages included in each of the processing modules, the transfer module, the load lock module, and the loader module are configured to be switchable.

21. A power supply system for supplying power to at least one of a substrate processing system, a substrate processing apparatus, a unit or a member using power, the system comprising:
a power transmitter including a power transmission coil to which power is supplied from an AC power supply source, and
a power receiver including a power reception coil to which power is transmitted from the power transmission coil in a non-contact manner,
wherein power is supplied from the power receiver to at least one of the substrate processing system, the substrate processing apparatus, the unit and the member.

22. The power supply system of claim 21, further comprising:
a power storage for storing power supplied from the power receiver,
wherein, between the power storage and an AC power supply source that supplies power to the power transmission coil, impedance at frequencies other than a frequency of transmitted AC power is set higher than impedance of the frequency of the transmitted AC power, and
a conversion part that converts AC power from the power reception coil into DC power is connected to the power storage.

23. The power supply system of claim 21, wherein the unit or member is provided in the substrate processing system including a plurality of units, and
the power receiver is disposed in each of the plurality of units.

24. The power supply system of claim 23, wherein the power transmitter is disposed on a bottom surface or under a bottom where the unit is installed.

25. The power supply system of claim 21, wherein the unit or member is provided in the substrate processing system including a plurality of units, and
the power receiver is disposed in the substrate processing system.

26. The power supply system of claim 25, wherein the power transmitter is disposed on a bottom surface or under a bottom where the substrate processing system is installed.

27. The power supply system of claim 21, further comprising:
a power storage for storing power supplied from the power receiver,
wherein, between the power storage and an AC power supply source that supplies power to the power transmission coil, impedance at frequencies other than a frequency of transmitted AC power is set higher than impedance of the frequency of the transmitted AC power,
a frequency conversion circuit that converts a frequency of power supplied from the AC power supply source to the power transmission coil into a transmission frequency and transmits power, and
a rectifying circuit and a smoothing circuit that rectify and smooth power supplied from the power reception coil to the power storage.

28. The power supply system of claim 22, wherein the power storage is a capacitor element or a battery.

29. A power supply method for supplying power to at least one of a substrate processing system, a substrate processing apparatus, a unit or a member using power, comprising:
supplying power from the power receiver to at least one of the substrate processing system, the substrate processing apparatus, the unit or the member, by using a power supply system including a power transmitter including a power transmission coil to which power is supplied from an AC power supply source, and a power receiver including a power reception coil to which power is transmitted from the power transmission coil in a non-contact manner.
